(19) United States
(12) Patent Application Publication
(10) Pub. No.: US 2025/0107100 A1
(43) Pub. Date: Mar. 27, 2025

(54) SEMICONDUCTOR MEMORY DEVICE

(71) Applicant: SAMSUNG ELECTRONICS CO, LTD., Suwon-si (KR)

(72) Inventors: JEON IL LEE, Suwon-si (KR); YOUNGIN GOH, Suwon-si (KR)

(73) Assignee: SAMSUNG ELECTRONICS CO, LTD., Suwon-si (KR)

(21) Appl. No.: 18/639,473

(22) Filed: Apr. 18, 2024

(30) Foreign Application Priority Data
Sep. 25, 2023 (KR) 10-2023-0128445

(51) Int. Cl. H10B 53/30

(52) U.S. Cl. CPC H10B 53/30

(57) ABSTRACT

A semiconductor memory device includes: a device isolation pattern in a semiconductor substrate and defining an active pattern extending in a first direction; a bit line crossing the active pattern on the semiconductor substrate and extending in a second direction forming an acute angle with the first direction; a word line extending across the active pattern in a third direction intersecting the second direction and extending into the semiconductor substrate; electrode plates vertically stacked on the bit line; a common electrode pattern extending through the electrode plates to the active pattern on one side of the bit line; and a ferroelectric pattern between the common electrode pattern and the electrode plates. The bit line is in contact with an upper surface of the active pattern and an upper surface of the device isolation pattern.

### CROSS-REFERENCE TO RELATED APPLICATION

This application claims priority to Korean Patent Application No.10-2023-0128445, filed on Sep. 25, 2023, in the Korean Intellectual Property Office, the disclosure of which is incorporated by reference herein in its entirety.

### BACKGROUND

The present disclosure relates to a semiconductor memory device, and more specifically, relates to a semiconductor memory device with improved electrical characteristics and integration.

Higher integration of semiconductor devices may help satisfy consumer demands for superior performance and reduced manufacturing complexity. In the case of semiconductor devices, as their integration is an important factor in determining manufacturing costs, increased integration may reduce manufacturing costs. In the case of typical two-dimensional or planar semiconductor devices, as their integration is mainly determined by the area occupied by a unit memory cell, integration is greatly influenced by the level of a fine pattern forming technology. However, the extremely expensive and complex process equipment used to increase pattern fineness sets a practical limitation on increasing integration for two-dimensional or planar semiconductor devices. Accordingly, semiconductor memory devices have been proposed to expand integration, reduce resistance, and increase current driving ability of semiconductor device.

### SUMMARY

One or more embodiments provide a semiconductor memory device with improved integration and electrical characteristics.

Problems to be solved by the present disclosure are not limited to the problems mentioned above, and other problems not mentioned will be clearly understood by those skilled in the art from the description below.

According to an aspect of an embodiment, a semiconductor memory device includes: a semiconductor substrate; a device isolation pattern in the semiconductor substrate and defining an active pattern extending in a first direction; a bit line crossing the active pattern on the semiconductor substrate and extending in a second direction forming an acute angle with the first direction; a word line extending across the active pattern in a third direction intersecting the second direction and extending into the semiconductor substrate; a plurality of electrode plates vertically stacked on the bit line; a common electrode pattern extending through the plurality of electrode plates to the active pattern on one side of the bit line; and a ferroelectric pattern between the common electrode pattern and the plurality of electrode plates. The bit line is in contact with an upper surface of the active pattern and an upper surface of the device isolation pattern.

According to an aspect of an embodiment, a semiconductor memory device includes: a semiconductor substrate; an active pattern in the semiconductor substrate and including a center portion and an edge portion extending from the center portion in a first direction; a device isolation pattern in the semiconductor substrate and defining the active pattern; a bit line including a metal pattern and a metal barrier pattern, the bit line crossing the active pattern in a second direction forming an acute angle with the first direction on the semiconductor substrate; a word line extending across the active pattern in a third direction intersecting the second direction and at least partially extending into the semiconductor substrate; a first interlayer insulating layer covering the bit line on the semiconductor substrate; a plurality of electrode plates vertically stacked on the bit line; a common electrode pattern extending through the plurality of electrode plates to the active pattern on one side of the bit line; a ferroelectric pattern between the common electrode pattern and the plurality of electrode plates; a capacitor contact extending through the first interlayer insulating layer on the active pattern, and between the common electrode pattern and the edge portion of the active pattern; and a second interlayer insulating layer covering the plurality of electrode plates on the first interlayer insulating layer. The metal barrier pattern of the bit line is in contact with an upper surface of the active pattern and an upper surface of the device isolation pattern.

According to an aspect of an embodiment, a semiconductor memory device including: a semiconductor substrate; active patterns including a center portion and an edge portion extending from the center portion in a first direction; a device isolation pattern in the semiconductor substrate and defining the active patterns; a bit line extending across the active patterns on the semiconductor substrate in a second direction forming an acute angle with the first direction; a word line extending across at least one of the active patterns in a third direction intersecting the second direction and at least partially extending into the semiconductor substrate; a first interlayer insulating layer covering the bit line on the semiconductor substrate; a plurality of electrode plates vertically stacked on the bit line and extending in the third direction; a pair of common electrode patterns extending through the plurality of electrode plates to the active patterns, and adjacent to each other in the first direction; ferroelectric patterns between the plurality of electrode plates and the pair of common electrode patterns; capacitor contacts extending through the first interlayer insulating layer on the active patterns, and between the pair of common electrode patterns and the edge portion of the active patterns; and a second interlayer insulating layer covering the plurality of electrode plates on the first interlayer insulating layer. The bit line is in contact with an upper surface of the active patterns and an upper surface of the device isolation pattern.

### BRIEF DESCRIPTION OF DRAWINGS

The above and other aspects and features will be more apparent from the following description of embodiments, taken in conjunction with the accompanying drawings. The accompanying drawings represent non-limiting, example embodiments as described herein.

FIG. 1A is a plan view showing a semiconductor memory device according to some embodiments.

FIGS. 1B and 1C are cross-sectional views corresponding to lines A-A′ and B-B′ of FIG. 1A, respectively, according to some embodiments.

FIG. 1D is a cross-sectional view showing the semiconductor memory device shown in FIG. 1A according to some embodiments.

FIG. 1E is a semiconductor memory device according to some embodiments.

FIG. 1F is a cross-sectional view corresponding to line A-A′ in FIG. 1E according to some embodiments.

FIG. 2A is a plan view showing a semiconductor memory device according to some embodiments.

FIG. 2B is a cross-sectional view corresponding to line A-A′ in FIG. 2A according to some embodiments.

FIG. 2C is a cross-sectional view showing the semiconductor memory device shown in FIG. 2A according to some embodiments.

FIG. 2D is a semiconductor memory device according to some embodiments.

FIG. 2E is a cross-sectional view corresponding to line A-A′ in FIG. 2D according to some embodiments.

FIG. 3A is a plan view showing a semiconductor memory device according to still some embodiments.

FIG. 3B is a cross-sectional view corresponding to line A-A′ in FIG. 3A according to some embodiments.

FIGS. 4A, 4B, 4C, 5A, 5B, 5C, 6A, 6B, 6C, 7A, 7B, 7C, 8A, 8B, 9A, 9B, 9C, 10A and 10B are diagrams showing a method of manufacturing a semiconductor memory according to some embodiments.

### DETAILED DESCRIPTION

Hereinafter, embodiments will be described in more detail with reference to the accompanying drawings. Each embodiment provided in the following description is not excluded from being associated with one or more features of another example or another embodiment also provided herein or not provided herein but consistent with the present disclosure. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. As used herein, the term “and/or” includes any and all combinations of one or more of the associated listed items. Expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c. It will be also understood that, even if a certain step or operation of manufacturing an apparatus or structure is described later than another step or operation, the step or operation may be performed later than the other step or operation unless the other step or operation is described as being performed after the step or operation.

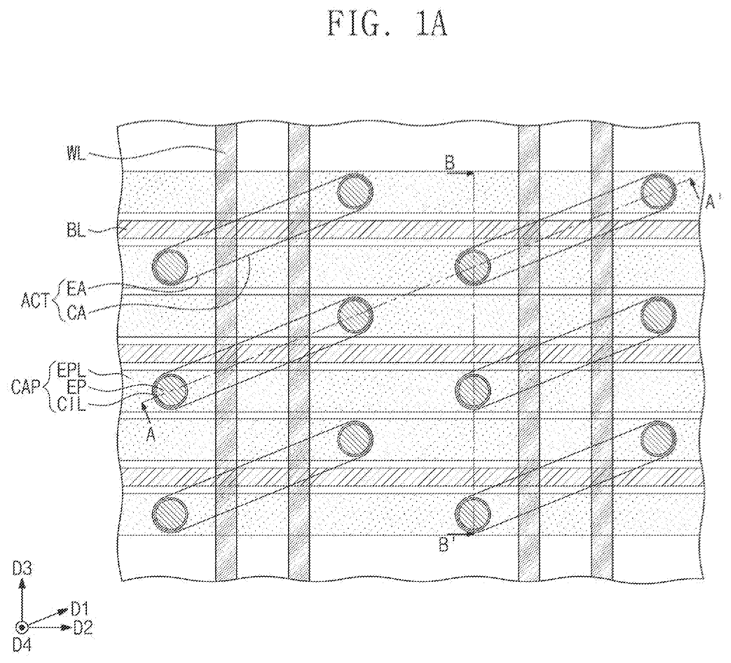

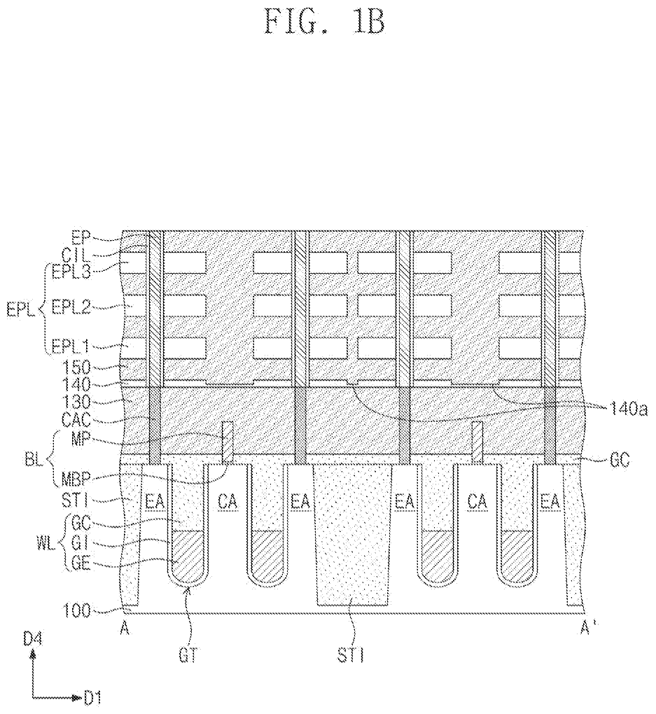

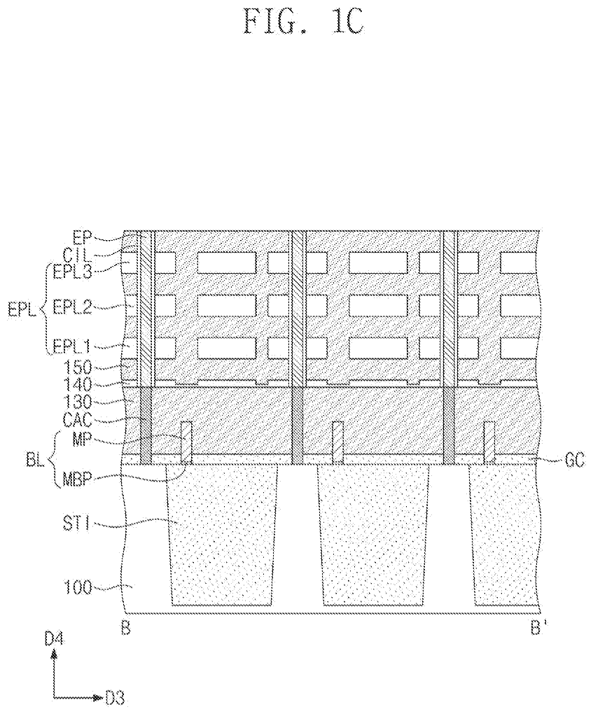

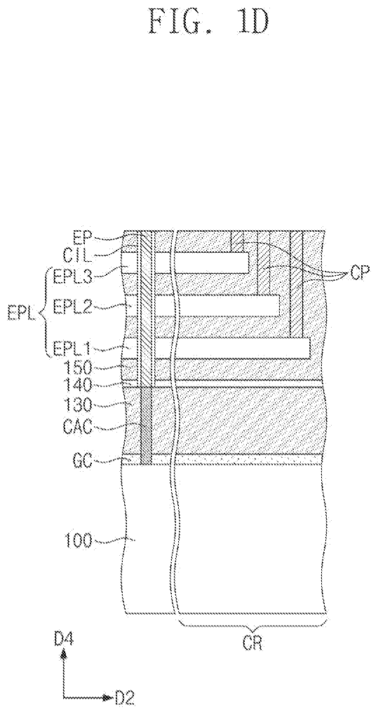

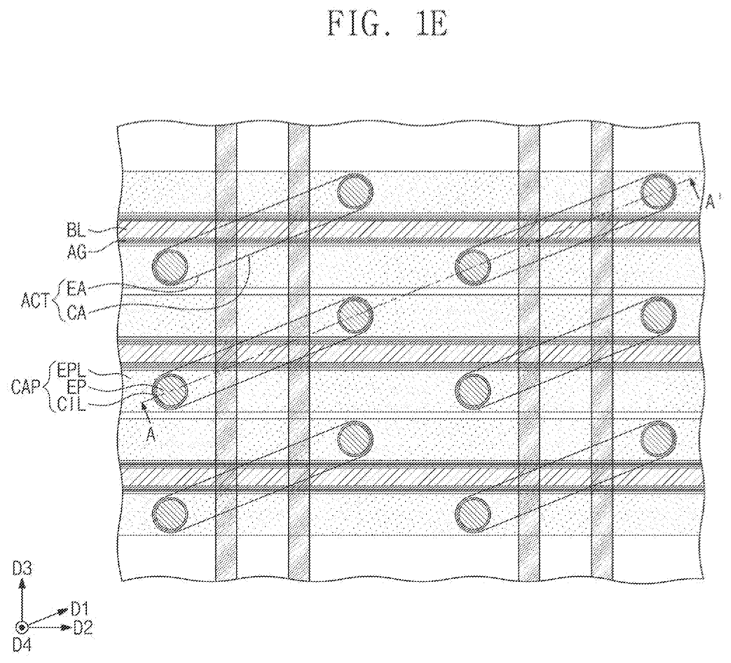

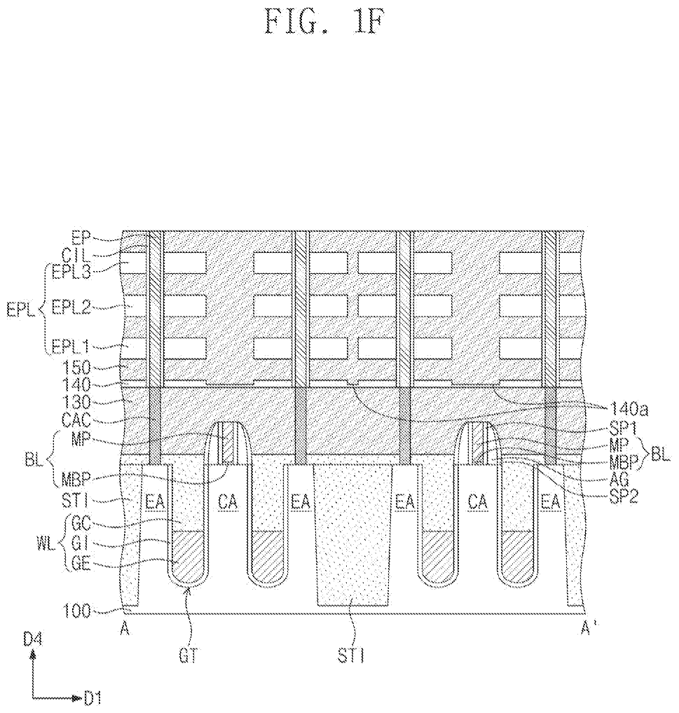

FIG. 1A is a plan view showing a semiconductor memory device according to some embodiments. FIGS. 1B and 1C are cross-sectional views corresponding to lines A-A′ and B-B′ of FIG. 1A, respectively. FIG. 1D is a cross-sectional view showing the semiconductor memory device shown in FIG. 1A.

Referring to FIGS. 1A to 1D, a semiconductor substrate 100 may be provided. The semiconductor substrate 100 may be, for example, a silicon substrate, a germanium substrate, or a silicon-germanium substrate.

A device isolation pattern STI may be disposed on the semiconductor substrate 100. The device isolation pattern STI may define active patterns ACT on the semiconductor substrate 100. Each of the active patterns ACT may include a center portion CA between a pair of word lines WL, which will be described later, and an edge portion EA extending from the center portion CA in a first direction. For example, a pair of edge portions EA may be spaced apart from each other with the center portion CA therebetween. For example, the pair of edge portions EA may be both end portions of the active pattern ACT in the first direction D1. That is, the pair of edge portions EA of the active pattern ACT may be spaced apart from each other in the first direction DI with the center portion CA therebetween, and may have a bar shape elongated in the first direction D1. The first direction D1 may form an acute angle with the direction D2 in which a bit line BL, which will be described later, extends. That is, the active pattern ACT may cross the bit line BL. The center portion CA and the pair of edge portions EA may each include an impurity region doped with an impurity (e.g., an n-type or p-type impurity).

For example, the active patterns ACT may include a single crystal or polycrystalline semiconductor material, a two-dimensional semiconductor material, and an oxide semiconductor material. The single crystal or polycrystalline semiconductor material may be single crystal silicon or polycrystalline silicon, and the two-dimensional semiconductor material may be a 2D TMD material. Additionally, the oxide semiconductor material may be, for example, at least one of CuS₂, CuSe₂, WSe₂, MoS₂, MoSe₂, WS₂, IZO, ZTO, YZO, and IGZO.

The active patterns ACT may be adjacent to each other in a second direction D2 and a third direction D3, which are parallel to a lower surface of the semiconductor substrate 100 and intersect each other. In this specification, a pair of active patterns ACT adjacent to each other in the second direction D2 and the third direction D3 may mean that their center portions CA are adjacent to each other in the second direction D2 and the third direction D3, respectively.

Each of the active patterns ACT may have a shape that protrudes in a fourth direction D4 perpendicular to an upper surface of the semiconductor substrate 100. As an example, the device isolation pattern STI may be disposed in the semiconductor substrate 100, and the active patterns ACT may be portions of the semiconductor substrate 100 surrounded by the device isolation pattern STI. For convenience of explanation, unless otherwise specified, in this specification, the semiconductor substrate 100 refers to other portions of the semiconductor substrate 100 excluding the active patterns ACT.

The device isolation pattern STI may include an insulating material. As an example, the device isolation pattern STI may include at least one of silicon oxide and silicon nitride. As an example, the device isolation pattern STI may be a single layer formed of any of the above materials or a composite layer formed of two or more of the above materials.

Word lines WL may be formed in a gate trench GT. As an example, the gate trench GT may be formed in the third direction D3 across the active patterns ACT and the device isolation pattern STI in the semiconductor substrate 100. Accordingly, the word lines WL may also be formed in the third direction D3 by being at least partially buried in (i.e., extending into) the semiconductor substrate 100,

A plurality of word lines WL may be provided. The plurality of word lines WL may be spaced apart from each other in the second direction D2. For example, a pair of word lines WL adjacent to each other in the second direction D2 may cross one active pattern ACT.

For example, each of the word lines WL may include a gate electrode GE, a gate insulating pattern GI, and a gate capping pattern GC. The gate electrode GE may cross the active patterns ACT and the device isolation pattern STI in the third direction D3. The gate insulating pattern GI may be interposed between the gate electrode GE and the active patterns ACT. The gate capping pattern GC may cover the upper surface of the semiconductor substrate 100 and a upper surface of the gate electrode GE. The gate capping pattern GC may include at least one of silicon oxide, silicon nitride, and silicon oxynitride.

A bit line BL may be provided on the semiconductor substrate 100 and may be provided in plural. The bit lines BL may be spaced apart from each other in the third direction D3.

The bit line BL may include a metal pattern MP and a metal barrier pattern MBP. The metal barrier pattern MBP may be in contact with the active pattern ACT on the semiconductor substrate 100. As an example, the metal barrier pattern MBP may include metal nitride, and may be in the form of a thin layer including TSN (Ti—Si—N). Additionally, the metal barrier MBP may include at least one of a single crystal or polycrystalline semiconductor material, a two-dimensional semiconductor material, and an oxide semiconductor material. The metal pattern MP may be disposed on the metal barrier pattern MBP. As an example, the metal pattern MP may include a metal material (e.g., Ti, Mo, W, Cu, Al, Ta, Ru, Ir, Co, Pt, Au, Ag, etc.). A metal silicide may be additionally disposed between the active pattern ACT and the metal barrier pattern MBP.

The bit line BL may be in contact with the active pattern ACT of the semiconductor substrate 100. The bit line BL may be in direct contact with an upper surface of the active pattern ACT and in direct contact with an upper surface of the device isolation pattern STI of the semiconductor substrate 100. For example, the metal barrier pattern MBP of the bit line BL may be in direct contact with the center portion CA of the active pattern ACT.

According to an embodiment, the semiconductor substrate 100 may be in direct contact with the bit line BL, and no other structures may be disposed between the bit line BL and the semiconductor substrate 100. For example, the center portion CA of the active pattern ACT may be in direct contact with the bit line BL, and no other structures may be disposed between the bit line BL and the center portion CA of the active pattern ACT. Specifically, when the active pattern ACT is disposed in at an acute angle with the bit line BL, a capacitor contact CAC disposed on both edge portions EA of the active pattern ACT may be disposed to be spaced apart from the bit line BL disposed on the center portion CA. Therefore, when the active pattern ACT is disposed parallel to the bit line BL, unlike other structures that should be placed between the bit line BL and the active pattern ACT to bypass the bit line BL, disposing the bit line BL on the semiconductor substrate 100 may simplify other structures on the semiconductor substrate 100, thereby reducing process costs. Additionally, the structure between adjacent bit lines BL may be simplified, parasitic capacitance that interferes with a flow of electrical signals transmitted to a circuit may be lowered, and sensing margin may be increased.

A first interlayer insulating layer 130 may be formed on the semiconductor substrate 100. For example, the first interlayer insulating layer 130 may cover the bit lines BL on the gate capping pattern GC. The first interlayer insulating layer 130 may include a single layer or a plurality of insulating layers. The first interlayer insulating layer 130 may include, for example, a silicon oxide layer, a silicon nitride layer, and/or a silicon oxynitride layer.

The capacitor contact CAC may be disposed on the semiconductor substrate 100 and penetrate the first interlayer insulating layer 130. One end of the capacitor contact CAC may be in contact with the active pattern ACT, and the other end of the capacitor contact CAC may be connected to the capacitors CAP. As an example, the capacitor contact CAC may be disposed between a common electrode pattern EP and the edge portion EA of the active pattern ACT, and may be disposed on both edge portions EA of the active pattern ACT, respectively. The capacitor contact CAC may include at least one of a metal material, a metal nitride layer, and a metal silicide.

Capacitors CAP may be connected to the capacitor contact CAC. The capacitor CAP may include a ferroelectric material or a combination of ferroelectric materials. A polarization state of a ferroelectric material of a ferroelectric capacitor may be variously changed depending on a voltage applied thereto, and the polarization state of the ferroelectric material may be maintained even when the power is turned off. That is, as the ferroelectric capacitor has non-volatile memory characteristics that retain data for a predetermined period of time, a region of the capacitor CAP may be reduced, thereby improving integration of the semiconductor memory device. Additionally, the ferroelectric capacitor may maintain data for a certain period of time depending on the applied voltage.

According to embodiments, a plurality of capacitors CAP may be connected to one capacitor contact CAC. That is, each memory cell may include one cell transistor and a plurality of capacitors CAP, and the cell transistor and the plurality of capacitors CAP may be electrically connected.

A common electrode pattern EP, an electrode plate EPL, and a ferroelectric pattern CIL interposed therebetween may constitute the capacitor CAP. For example, in the capacitors CAP, the common electrode pattern EP may be used as an internal electrode, and the electrode plates EPL may be used as an external electrode. That is, the common electrode pattern EP and the plurality of electrode plates EPL surrounding the common electrode pattern EP may form a plurality of capacitors CAP.

The common electrode pattern EP may be extended in the fourth direction D4. The common electrode pattern EP may penetrate the plurality of electrode plates EPL and may be electrically connected to the active pattern ACT through the capacitor contact CAC. The common electrode pattern EP may include at least one of a metal material, a metal nitride layer, and a metal silicide.

The ferroelectric pattern CIL may conformally cover a surface of the common electrode patterns EP. The ferroelectric pattern CIL may include a ferroelectric material. As an example, the ferroelectric material may include pervoskite materials such as BaTiOx and hafnium (Hf)-based materials. When the ferroelectric includes a hafnium-based oxide, a dopant may include at least one of zirconium (Zr), silicon (Si), aluminum (Al), yttrium (Y), gadolinium (Gd), lanthanum (La), scandium (Sc), and strontium (Sr). As an example, the ferroelectric pattern CIL may include a plurality of ferroelectric layers, and each of the plurality of ferroelectric layers may include different ferroelectric materials.

A polarization state of a ferroelectric may be variously changed depending on a voltage applied thereto, and the polarization state of the ferroelectric may be maintained even when the power is turned off. Accordingly, data stored in the ferroelectric pattern CIL may be maintained for a predetermined period of time depending on the voltage applied to the electrode plate EPL.

The electrode plate EPL may surround a portion of the common electrode pattern EP and the ferroelectric pattern CIL. For example, the electrode plate EPL may extend in the second direction D2 and may surround the common electrode patterns EP arranged in the second direction D2.

The electrode plate EPL may be vertically stacked on the bit line BL and may be provided in plural. For example, the electrode plates EPL may be spaced apart in the third direction D3 and vertically spaced apart in the fourth direction D4 perpendicular to the upper surface of the semiconductor substrate 100. Each EPL1, EPL2, or EPL3 of the vertically spaced electrode plates EPL may form one capacitor CAP together with the common electrode pattern EP and the ferroelectric pattern CIL. For example, as shown in FIGS. 1B and 1C, each of the electrode plates EPL1, EPL2, and EPL3 may form three capacitors CAP together with a ferroelectric pattern CIL and a common electrode pattern EP. The number of capacitors CAP is not limited to three as shown in FIGS. 1A to 1D and may be variously changed depending on the number of electrode plates EPL disposed. The electrode plates EPL may include at least one of a metal material, a metal nitride layer, and a metal silicide. In this specification, only three electrode plates EPL1, EPL2, and EPL3 arranged in the fourth direction D4 are shown for convenience of explanation, but embodiments are not limited to the number of electrode plates EPL, and the number of electrode plates EPL disposed may be variously changed.

The electrode plates EPL1, EPL2, and EPL3 may be stacked in a stepped structure on the connection region CR. For example, lengths of each of the electrode plates EPL1, EPL2, and EPL3 in the second direction D2 may be different, and end portions of the electrode plates EPL1, EPL2, and EPL3 in the second direction D2 may form a stepped structure. Contact plugs CP may be connected to the end portions of the electrode plates EPL1, EPL2, and EPL3, respectively.

An etch stop layer 140 may be disposed on the first interlayer insulating layer 130. The etch stop layer 140 may serve as an etch stop during the semiconductor memory device manufacturing process, which will be described later. A portion 140a of an upper surface of the etch stop layer 140 may be etched during an etching process and may be positioned at a low level (i.e., the portion 140a of the upper surface of the etch stop layer 140 may be closer to the semiconductor substrate 100 than other portions of the upper surface of the etch stop layer 140).

A second interlayer insulating layer 150 may be disposed on the etch stop layer 140. The second interlayer insulating layer 150 may include a single layer or a plurality of insulating layers. The second interlayer insulating layer 150 may include, for example, a silicon oxide layer, a silicon nitride layer, and/or a silicon oxynitride layer. The second interlayer insulating layer 150 may cover the electrode plates EPL.

FIG. 1E is a plan view showing a semiconductor memory device according to some embodiments. For example, the semiconductor device shown in FIG. 1E is a modified example of the semiconductor memory device shown in FIG. 1A. FIG. 1F is a cross-sectional view corresponding to line A-A′ in FIG. 1E. To simplify the explanation, descriptions of content that overlaps with the above-described content will be omitted and the differences will be mainly explained.

Referring to FIG. 1E, an air gap AG may be formed between the bit line BL and the capacitor contact CAC. For example, first and second spacers SP1 and SP2 may be disposed on both walls of the bit line BL, and the air gap AG may be formed between the first spacer SP1 and the second spacer SP2. That is, the air gap AG is disposed between the bit line BL and the capacitor contact CAC. The air gap AG may reduce parasitic capacitance between the bit line BL and the capacitor contact CAC. As an example, the air gap AG may be formed by disposing a molding layer between the first and second spacers SP1 and SP2 and then removing the molding layer disposed between the first spacer SP1 and the second spacer SP2, but embodiments are not limited thereto. Each of the first and second spacers SP1 and SP2 may include at least one of silicon nitride, silicon oxide, and silicon oxynitride. For example, each of the first and second spacers SP1 and SP2 may be formed of a single layer or a multilayer.

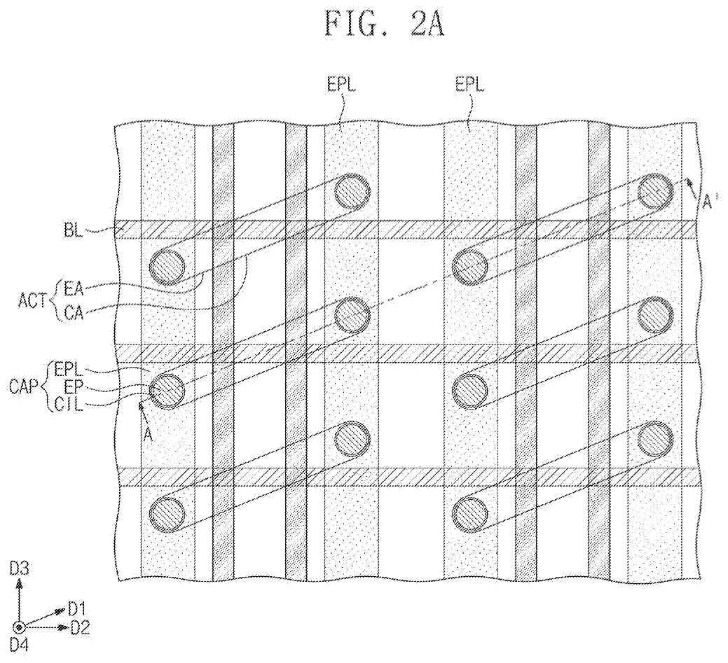

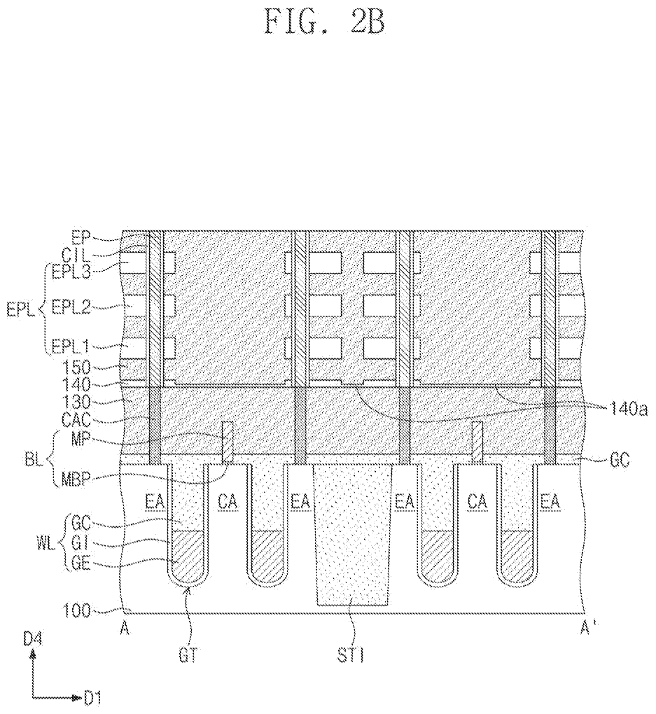

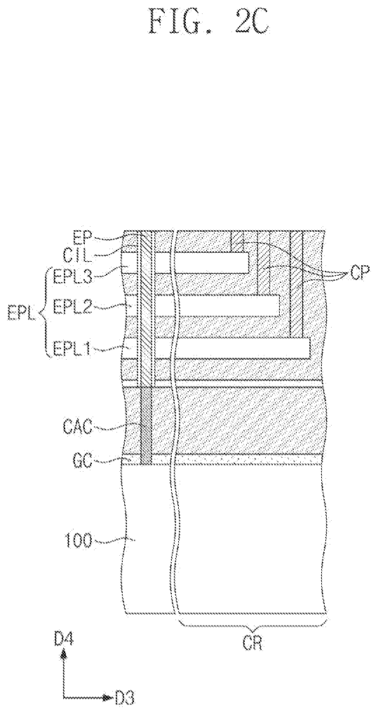

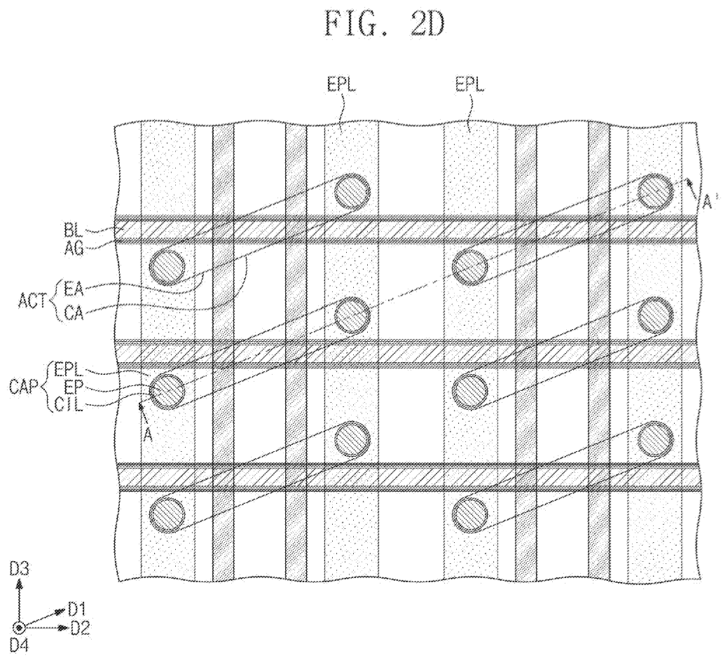

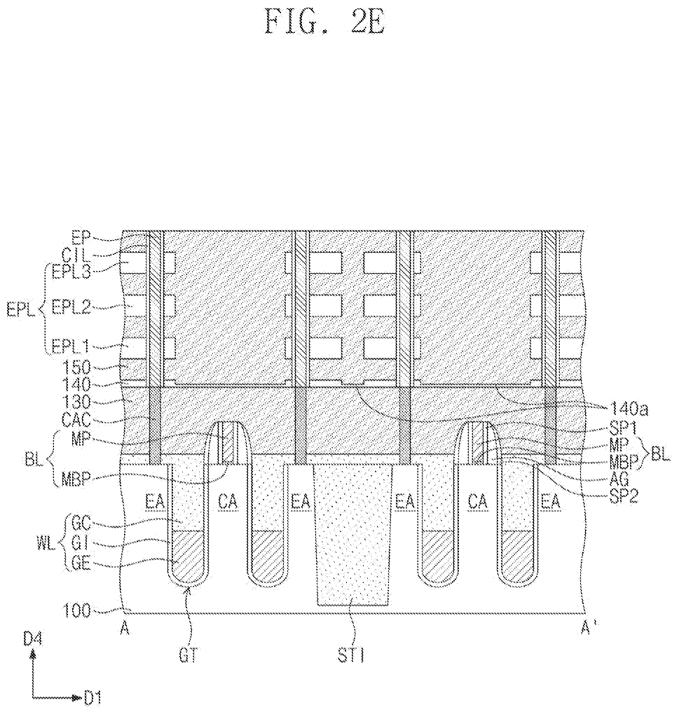

FIG. 2A is a plan view showing a semiconductor memory device according to another embodiment. FIG. 2B is a cross-sectional view corresponding to line A-A′ in FIG. 2A. FIG. 2C is a cross-sectional view showing the semiconductor memory device shown in FIG. 2A. To simplify the explanation, descriptions of content that overlaps with the above-described content will be omitted and the differences will be mainly explained.

Each of the electrode plates EPL may extend in the third direction D3 and may surround the common electrode patterns EP arranged in the third direction D3.

The electrode plates EPL may be vertically stacked on the bit line BL and may be provided in plural. For example, the electrode plates EPL may be spaced apart in the second direction D2 and vertically spaced apart in the fourth direction D4 perpendicular to the upper surface of the semiconductor substrate 100. Each EPL1, EPL2, or EPL3 of the vertically spaced electrode plates EPL may form each capacitor CAP together with the common electrode pattern EP and the ferroelectric pattern CIL. For example, as shown in FIGS. 2A and 2B, the electrode plates EPL1, EP2 and EPL3 may form three capacitors CAP together with the ferroelectric pattern CIL and the common electrode pattern EP.

The electrode plates EPL1, EPL2, and EPL3 may be stacked in a stepped structure on the connection region CR. For example, lengths of each of the electrode plates EPL1, EPL2, and EPL3 in the third direction D3 may be different, and end portions of the electrode plates EPL1, EPL2, and EPL3 in the third direction D3 may form a stepped structure. Contact plugs CP may be connected to end portions of the electrode plates EPL1, EPL2, and EPL3, respectively.

Similarly, in this specification, only three electrode plates EPL1, EPL2, and EPL3 vertically arranged in the fourth direction D4 are shown for convenience of explanation, but embodiments are not limited to the number of electrode plates EPL, and the number of electrode plates EPL disposed may be variously changed.

FIG. 2D is a plan view showing a semiconductor memory device according to some embodiments. For example, the semiconductor device shown in FIG. 2D is a modified example of the semiconductor memory device shown in FIG. 2A. FIG. 2E is a cross-sectional view corresponding to line A-A′ in FIG. 2D.

Referring to FIGS. 2D and 2E, an air gap AG may be formed between the bit line BL and the capacitor contact CAC. For example, the first and second spacers SP1 and SP2 may be disposed on both walls of the bit line BL, and the air gap AG may be formed between the first spacer SP1 and the second spacer SP2. That is, the air gap AG may be disposed between the bit line BL and the capacitor contact CAC. The air gap AG may reduce parasitic capacitance between the bit line BL and the capacitor contact CAC.

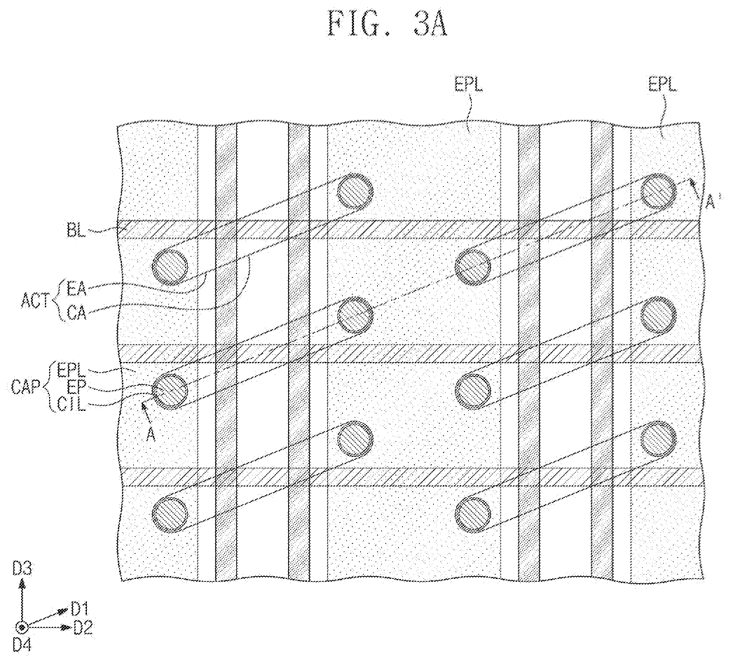

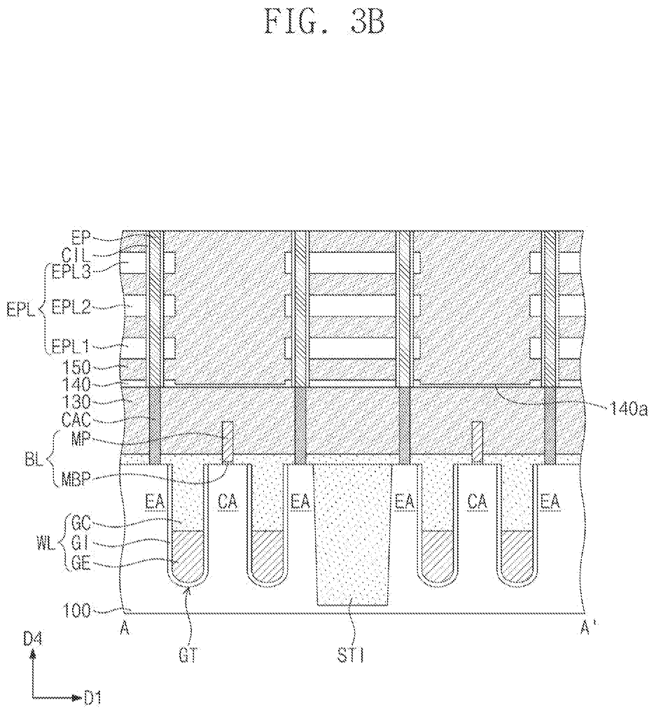

FIG. 3A is a plan view showing a semiconductor memory device according to embodiments. FIG. 3B is a cross-sectional view corresponding to line A-A′ in FIG. 3A. To simplify the explanation, descriptions of content that overlaps with the above-described content will be omitted and the differences will be mainly explained.

Referring to FIGS. 3A and 3B, an electrode plate EPL may extend in the third direction D3 and may surround a common electrode pattern EP arranged in the third direction D3. In this case, each of the electrode plates EPL1, EPL2, and EPL3 may surround the common electrode patterns EP disposed adjacent to each other in the first direction D1. That is, capacitors CAP adjacent to each other in the first direction DI may share the electrode plates EPL.

As described above with reference to FIGS. 2A to 2D, the electrode plates EPL may be electrically connected to the contact plug CP (of FIG. 2C) at an end thereof in the third direction D3.

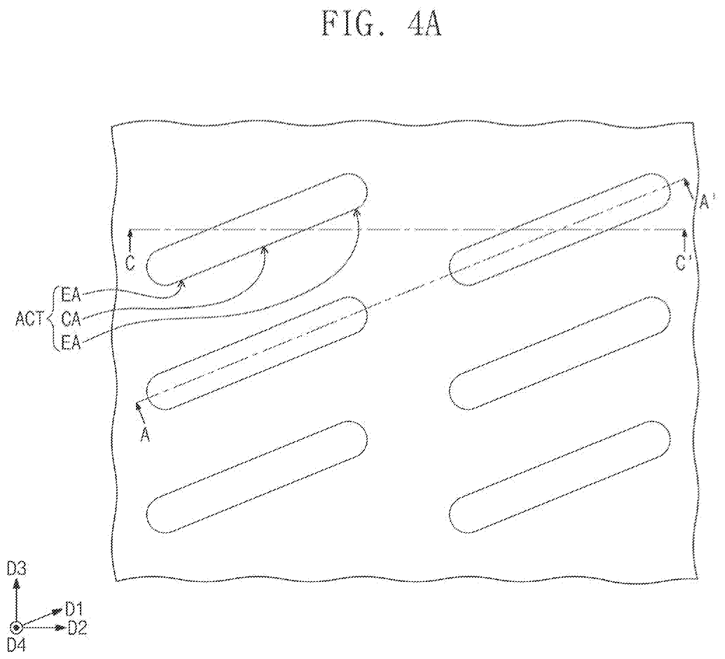

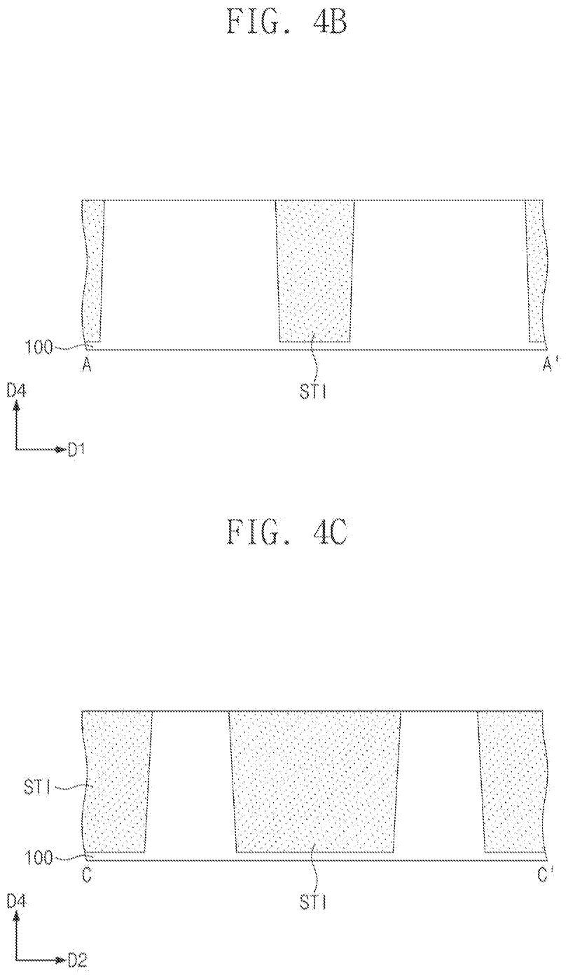

A method of manufacturing a semiconductor memory device according to embodiments will be described with reference to FIGS. 4A to 10B.

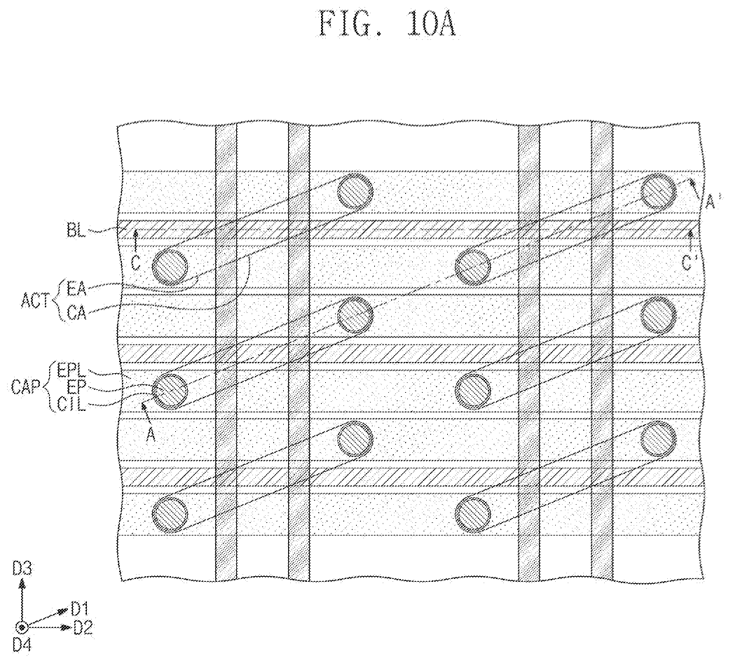

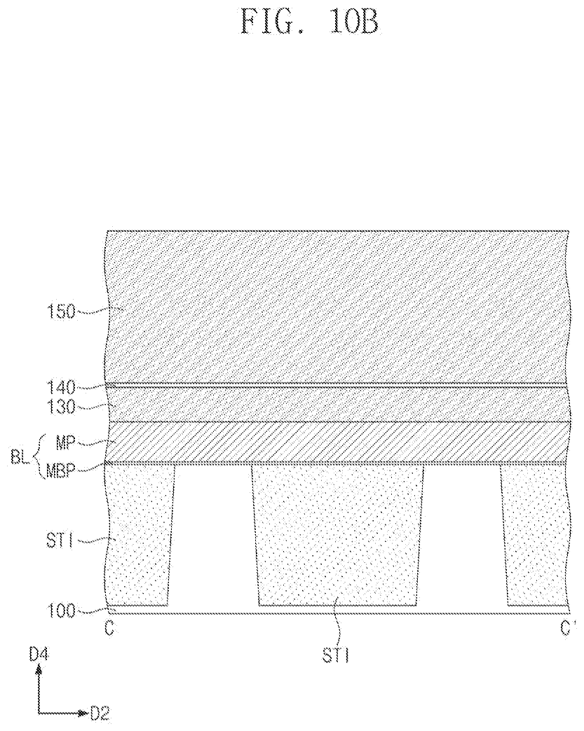

FIGS. 4A to 10B are diagrams showing a method of manufacturing a semiconductor memory according to some embodiments. FIGS. 4B, 5B, 6B, 7B, 8B and 9B are cross-sectional views corresponding to line A-A′ of FIGS. 4A, 5A, 6A, 7A, 8A and 9A. FIGS. 4C, 5C, 6C, 7C and 9C are cross-sectional views corresponding to line C-C′ of FIGS. 4A, 5A, 6A, 7A and 9A. FIG. 10B is a cross-sectional view corresponding to line C-C′ of FIG. 10A.

First, referring to FIGS. 4A to 4C, a semiconductor substrate 100 may be provided. A device isolation pattern STI and active patterns ACT may be formed on the semiconductor substrate 100. The semiconductor substrate 100 may be patterned to form a trench region in the semiconductor substrate 100 and the trench region may be filled with an insulating material, thereby forming the device isolation pattern STI and the active patterns. The active patterns ACT may be a portion of the semiconductor substrate 100 in which the trench region is not formed.

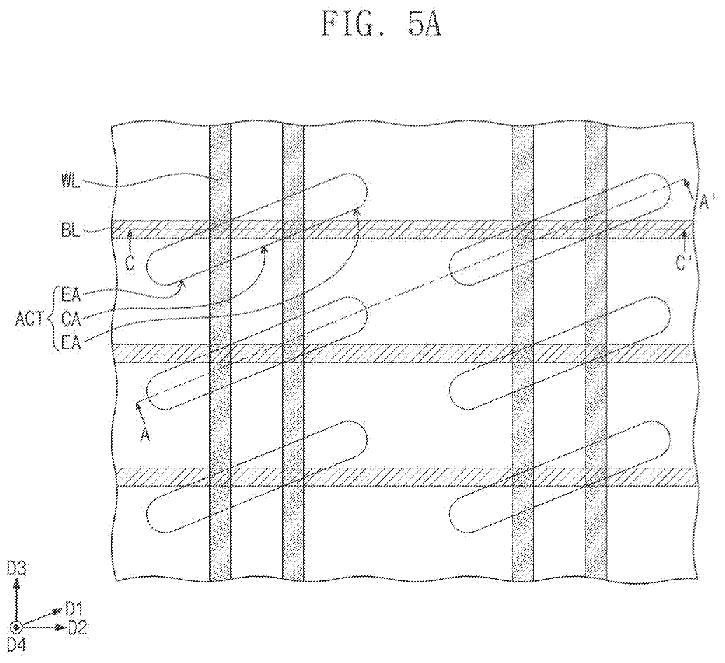

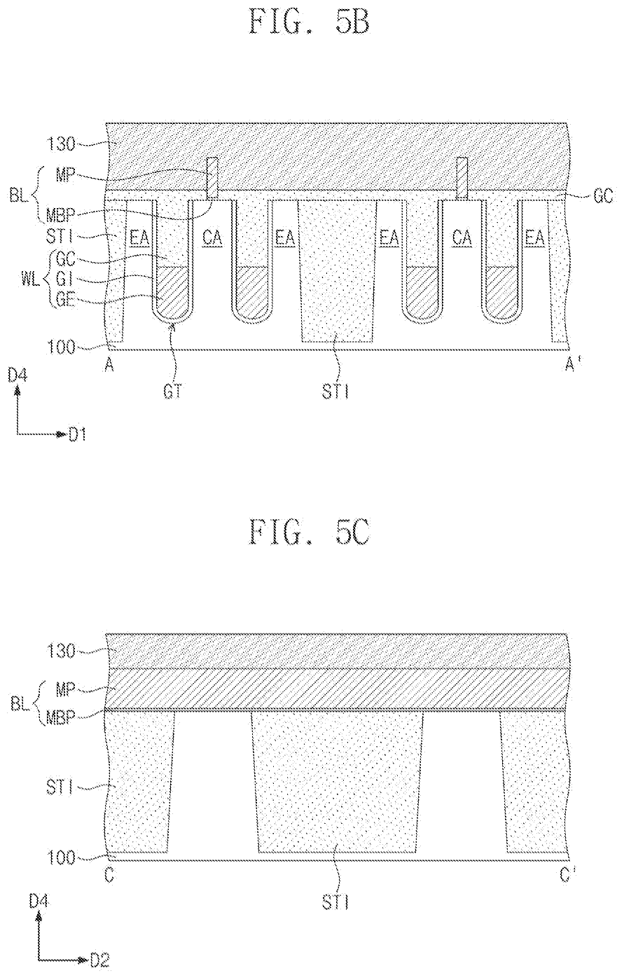

Referring to FIGS. 5A to 5C, word lines WL may be formed by forming mask patterns on the active pattern ACT and the device isolation pattern STI, performing an anisotropic etching process using the mask patterns to form gate trenches GT, and filling the gate trenches GT with the word lines WL. For example, a gate insulation pattern GI may conformally cover the gate trenches GT, and the gate electrodes GE may fill the gate trenches GT in which the gate insulation pattern GI is formed. Thereafter, a gate capping pattern GC may be disposed on the gate electrodes GE, and the gate capping pattern GC may cover an upper surface of the semiconductor substrate 100 and upper surfaces of the gate electrodes GE. As an example, a pair of word lines WL may cross the active pattern ACT, and a center portion CA of the active pattern ACT may be defined between the pair of word lines WL. Other portions of the active pattern ACT spaced apart from the center portion CA with each pair of word lines WL therebetween may be defined as edge portions EA.

A bit line BL may be formed to cross the active patterns ACT and the device isolation pattern STI in a second direction D2 on the semiconductor substrate 100.

The gate capping pattern GC may be patterned to form an opening exposing portions of the device isolation pattern STI and the center portions CA of the active patterns ACT in the second direction D2. Thereafter, a metal barrier pattern MBP and a metal pattern MP may be sequentially deposited on the gate capping pattern GC in which the opening is formed. Next, the metal barrier pattern MBP and the metal pattern MP may be formed in a line shape to form the bit line BL.

A first interlayer insulating layer 130 may be formed on the semiconductor substrate 100 and the gate capping pattern GC. The first interlayer insulating layer 130 may cover the bit lines BL on the gate capping pattern GC.

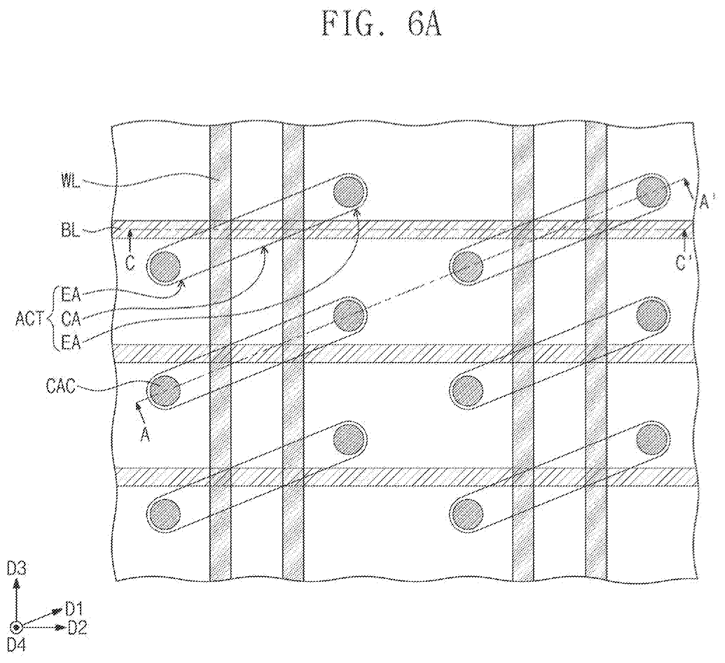

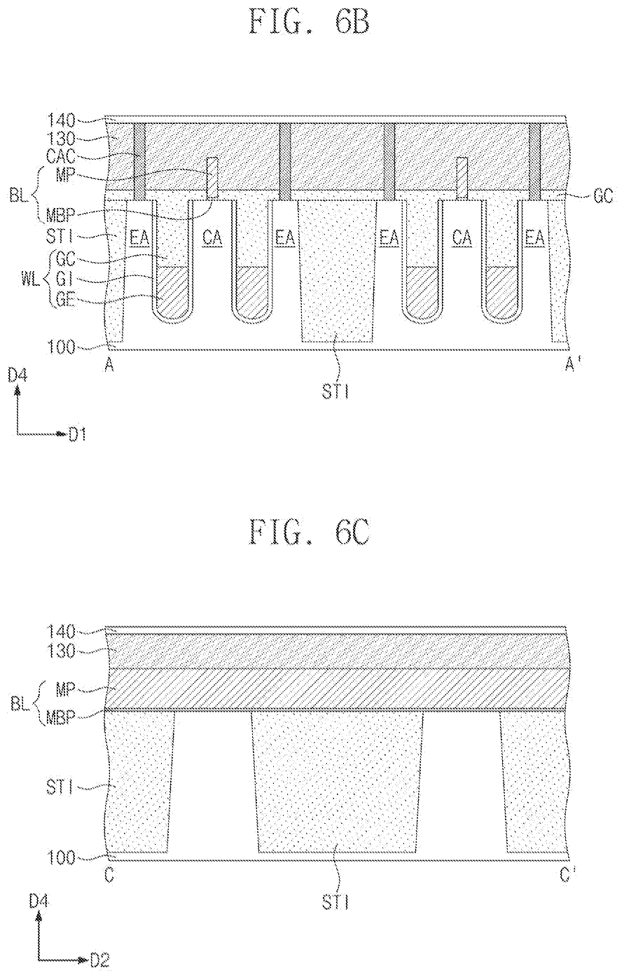

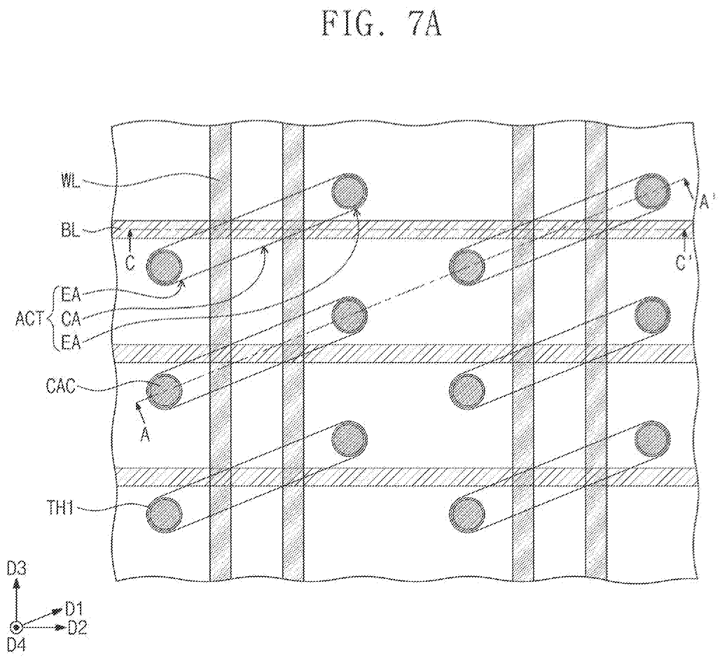

Referring to FIGS. 6A to 6C, a capacitor contact CAC may be formed through the first interlayer insulating layer 130 and the gate capping pattern GC. As an example, a mask pattern may be formed on the first interlayer insulating layer 130, the first interlayer insulating layer 130 and the gate capping pattern GC may be etched using the mask pattern as an etch mask to form contact holes that expose the edge portions EA of the active patterns ACT, and a conductive material may be filled in contact holes, thereby forming the capacitor contact CAC.

An etch stop layer 140 may be formed on the first interlayer insulating layer 130. The etch stop layer 140 may cover the capacitor contact CAC and the first interlayer insulating layer 130.

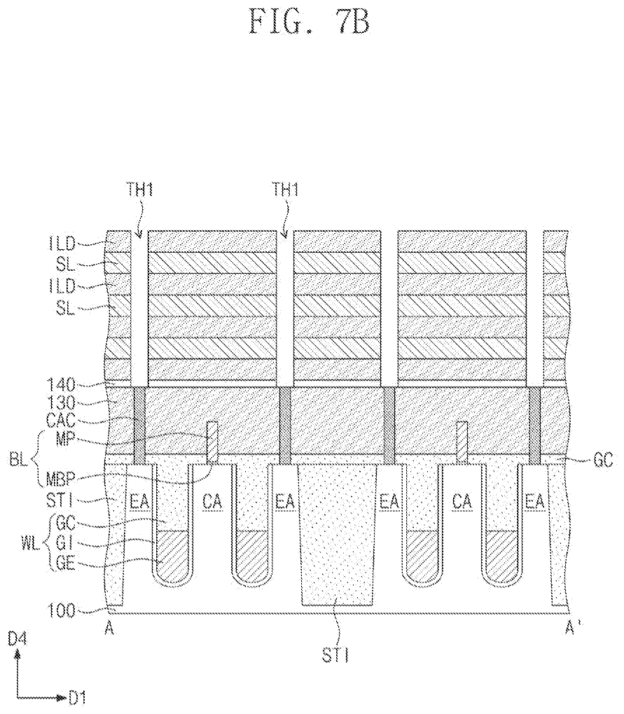

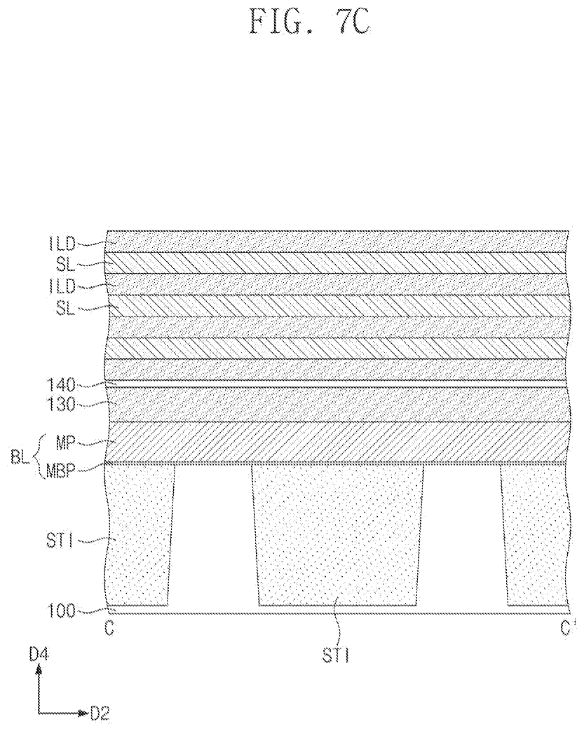

Referring to FIGS. 7A to 7C, sacrificial layers SL and insulating layers ILD may be alternately deposited on the etch stop layer 140. The sacrificial layers SL and the insulating layers ILD may include different materials. For example, the sacrificial layers SL may include a silicon nitride layer, and the insulating layers ILD may include a silicon oxide layer. Thereafter, the sacrificial layers SL and the insulating layers ILD may be patterned to form a first through hole TH1 on the capacitor contact CAC.

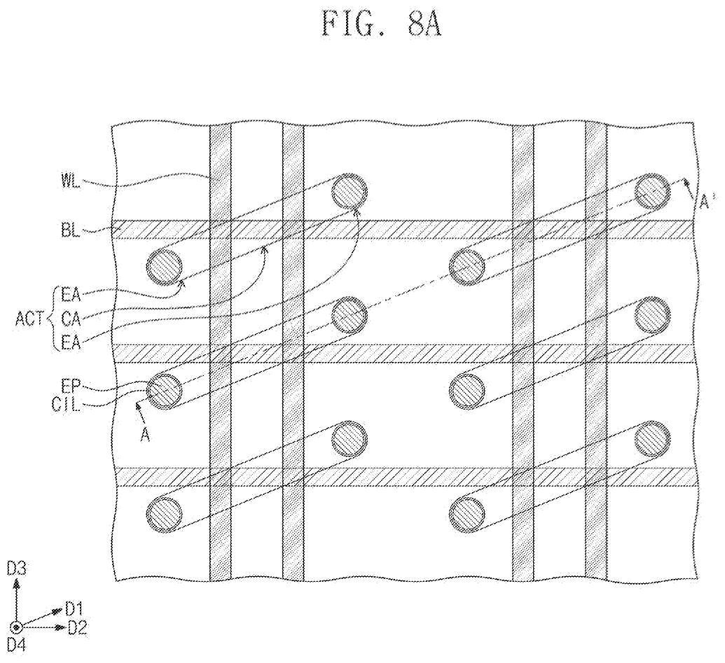

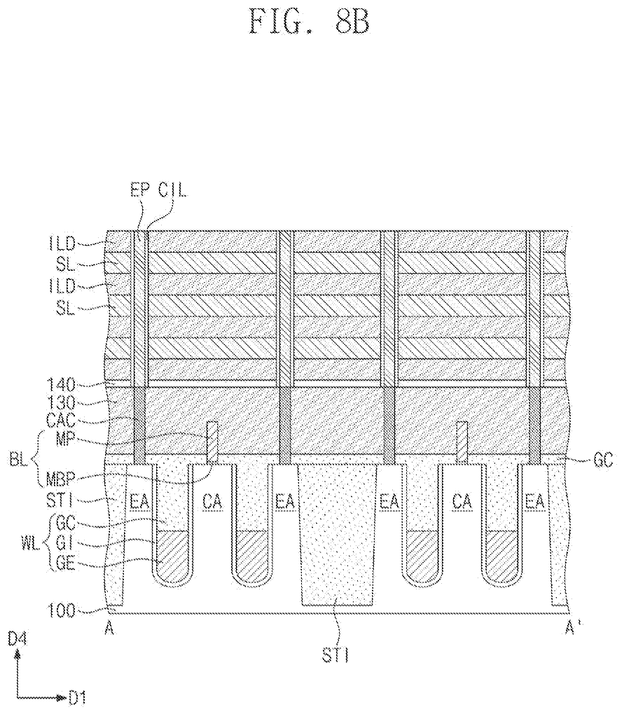

Referring to FIGS. 8A and 8B, the first through hole TH1 formed in FIG. 7B may be filled with a common electrode pattern EP and a ferroelectric pattern CIL. The ferroelectric pattern CIL may be formed along ab outer circumference of the first through hole TH1, and the common electrode pattern EP may be filled in the first through hole TH1 in which the ferroelectric pattern CIL is formed.

For example, forming the ferroelectric pattern CIL may include depositing a ferroelectric layer conformally covering a surface where the first through hole TH1 (of FIG. 7B) is formed and an upper surface of the uppermost insulating layer ILD, and performing an etch-back process to etch the ferroelectric layer on the upper surface of the uppermost insulating layer ILD and a lower surface of the first through hole TH1 (of FIG. 7B) to expose an upper surface of the capacitor contact CAC. Thereafter, a conductive material may be filled in the first through hole TH1 (of FIG. 7B) in which the ferroelectric pattern CIL is formed to form the common electrode pattern EP.

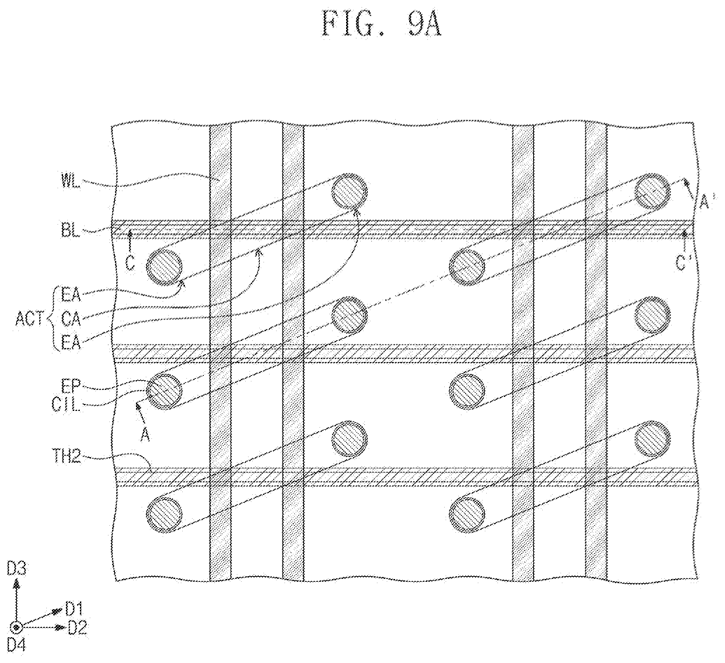

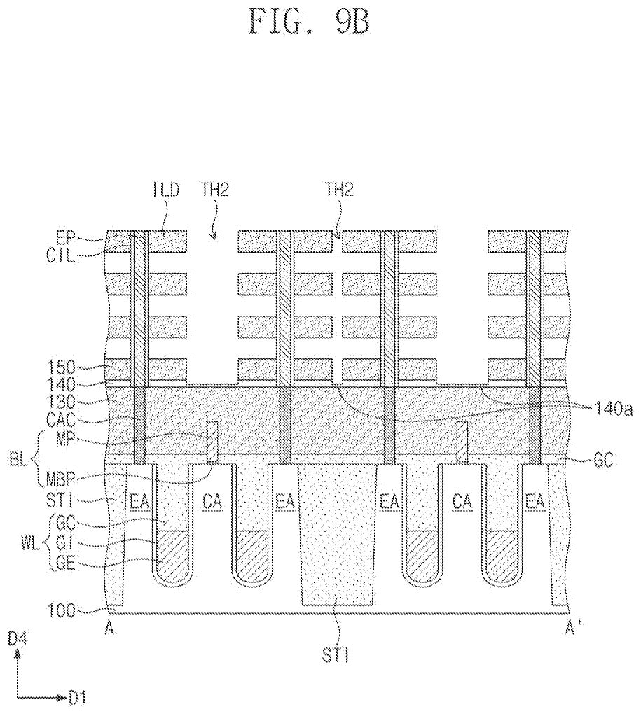

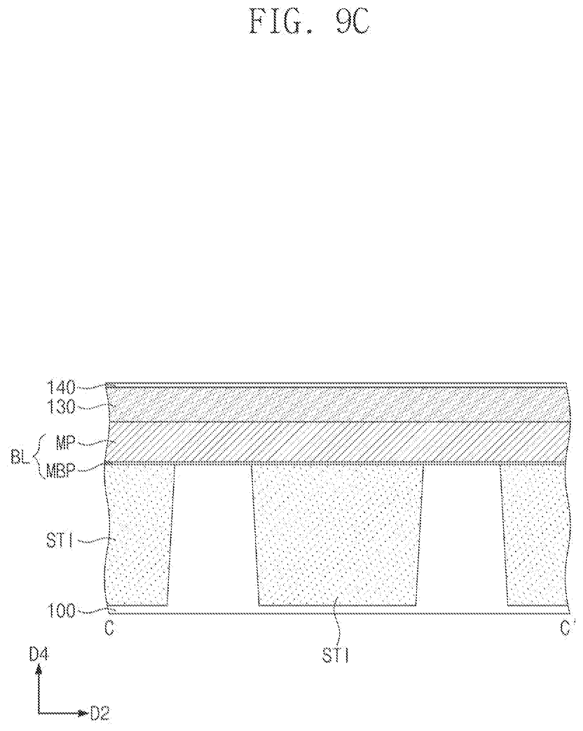

Referring to FIGS. 9A to 9C, a second through hole TH2 exposing the etch stop layer 140 may be formed by patterning the sacrificial layers SL and the insulating layers ILD. The second through hole TH2 may be a trench formed in the second direction D2. Referring to FIGS. 9B and 9C, the etching process may be performed in the second direction D2, but is not limited thereto, and may be variously changed depending on a shape of the electrode plate EPL. For example, when the electrode plate EPL is formed to extend in the third direction D3, the second through hole TH2 may be a trench formed in the third direction D3.

The sacrificial layers SL (of FIG. 8) may be removed through the second through hole TH2. As an example, a wet etching process may be performed using an etch recipe that has etch selectivity for the insulating layers ILD.

Referring to FIGS. 10A, 10B, and 1B, preliminary electrode plates may be filled between vertically adjacent insulating layers ILD in a fourth direction D4 through the second through hole TH2. After the preliminary electrode plates are filled, the preliminary electrode plates may be etched by performing a dry etching process. For example, side surfaces of the preliminary electrode plates may be etched to form vertically separated electrode plates EPL in the fourth direction D4. Thereafter, the second through hole TH2 (of FIG. 9B) may be filled with an insulating layer to form a second interlayer insulating layer 150 that fills a space between the electrode plates EPL spaced apart in the third direction D3.

According to embodiments, in the semiconductor memory device in which each of the memory cells includes one transistor and a plurality of capacitors, the active pattern that may be non-parallel to the bit line and the word line is provided, to directly connect the bit line to the active pattern. Accordingly, the contact connecting the bit line and the active pattern is omitted, the parasitic capacitance between adjacent conductive patterns may be reduced, and the manufacturing cost of the semiconductor memory device may be reduced.

While aspects of embodiments have been particularly shown and described, it will be understood that various changes in form and details may be made therein without departing from the spirit and scope of the following claims.

What is claimed is:

1. A semiconductor memory device comprising:
a semiconductor substrate;
a device isolation pattern in the semiconductor substrate and defining an active pattern extending in a first direction;
a bit line crossing the active pattern on the semiconductor substrate and extending in a second direction forming an acute angle with the first direction;
a word line extending across the active pattern in a third direction intersecting the second direction and extending into the semiconductor substrate;
a plurality of electrode plates vertically stacked on the bit line;
a common electrode pattern extending through the plurality of electrode plates to the active pattern on one side of the bit line; and
a ferroelectric pattern between the common electrode pattern and the plurality of electrode plates,
wherein the bit line is in contact with an upper surface of the active pattern and an upper surface of the device isolation pattern.

2. The semiconductor memory device of claim 1, wherein the bit line comprises a metal pattern and a metal barrier pattern, and
wherein the metal barrier pattern of the bit line is in contact with the upper surface of the active pattern.

3. The semiconductor memory device of claim 1, wherein the active pattern comprises a center portion and an edge portion extending from the center portion in the first direction, and
wherein the bit line is in contact with the center portion of the active pattern.

4. The semiconductor memory device of claim 3, further comprising:
a first interlayer insulating layer covering the bit line on the semiconductor substrate; and
a capacitor contact extending into the first interlayer insulating layer, and between the common electrode pattern and the edge portion of the active pattern.

5. The semiconductor memory device of claim 1, further comprising:
first and second spacers on sidewalls of the bit line on the semiconductor substrate; and
an air gap between the first and second spacers.

6. The semiconductor memory device of claim 1, wherein the plurality of electrode plates extend in the second direction.

7. The semiconductor memory device of claim 6, wherein the plurality of electrode plates form a stepped structure at end portions thereof in the second direction, and
wherein the plurality of electrode plates are connected to contact plugs at the end portions thereof in the second direction.

8. The semiconductor memory device of claim 1, wherein the plurality of electrode plates extend in the third direction.

9. The semiconductor memory device of claim 8, wherein the plurality of electrode plates form a stepped structure at end portions thereof in the third direction, and
wherein the plurality of electrode plates are connected to contact plugs at the end portions thereof in the third direction.

10. The semiconductor memory device of claim 1, wherein the ferroelectric pattern comprises a plurality of ferroelectric layers.

11. The semiconductor memory device of claim 1, wherein the ferroelectric pattern comprises hafnium oxide and at least one of zirconium (Zr), silicon (Si), aluminum (Al), yttrium (Y), gadolinium (Gd), lanthanum (La), scandium (Sc), and strontium (Sr).

12. The semiconductor memory device of claim 1, wherein the active pattern comprises a single crystal or polycrystalline semiconductor material, a two-dimensional semiconductor material, or an oxide semiconductor material.

13. A semiconductor memory device comprising:
a semiconductor substrate;
an active pattern in the semiconductor substrate and comprising a center portion and an edge portion extending from the center portion in a first direction;
a device isolation pattern in the semiconductor substrate and defining the active pattern;
a bit line comprising a metal pattern and a metal barrier pattern, the bit line crossing the active pattern in a second direction forming an acute angle with the first direction on the semiconductor substrate;
a word line extending across the active pattern in a third direction intersecting the second direction and at least partially extending into the semiconductor substrate;
a first interlayer insulating layer covering the bit line on the semiconductor substrate;
a plurality of electrode plates vertically stacked on the bit line;
a common electrode pattern extending through the plurality of electrode plates to the active pattern on one side of the bit line;
a ferroelectric pattern between the common electrode pattern and the plurality of electrode plates;
a capacitor contact extending through the first interlayer insulating layer on the active pattern, and between the common electrode pattern and the edge portion of the active pattern; and
a second interlayer insulating layer covering the plurality of electrode plates on the first interlayer insulating layer,
wherein the metal barrier pattern of the bit line is in contact with an upper surface of the active pattern and an upper surface of the device isolation pattern.

14. The semiconductor memory device of claim 13, wherein the ferroelectric pattern comprises hafnium oxide and at least one of zirconium (Zr), silicon (Si), aluminum (Al), yttrium (Y), gadolinium (Gd), lanthanum (La), scandium (Sc), and strontium (Sr).

15. The semiconductor memory device of claim 13, wherein the active pattern comprises a single crystal or polycrystalline semiconductor material, a two-dimensional semiconductor material, or an oxide semiconductor material.

16. The semiconductor memory device of claim 13, wherein the plurality of electrode plates extend in the second direction,
wherein the plurality of electrode plates form a stepped structure at end portions thereof in the second direction, and
wherein the plurality of electrode plates are connected to contact plugs at the end portions thereof in the second direction.

17. The semiconductor memory device of claim 13, wherein the plurality of electrode plates extend in the third direction,
wherein the plurality of electrode plates form a stepped structure at end portions thereof in the third direction, and
wherein the plurality of electrode plates are connected to contact plugs at the end portions thereof in the third direction.

18. The semiconductor memory device of claim 13, further comprising:
first and second spacers on sidewalls of the bit line on the semiconductor substrate; and
an air gap between the first and second spacers.

19. A semiconductor memory device comprising:
a semiconductor substrate;
active patterns comprising a center portion and an edge portion extending from the center portion in a first direction;
a device isolation pattern in the semiconductor substrate and defining the active patterns;
a bit line extending across the active patterns on the semiconductor substrate in a second direction forming an acute angle with the first direction;
a word line extending across at least one of the active patterns in a third direction intersecting the second direction and at least partially extending into the semiconductor substrate;
a first interlayer insulating layer covering the bit line on the semiconductor substrate;
a plurality of electrode plates vertically stacked on the bit line and extending in the third direction;
a pair of common electrode patterns extending through the plurality of electrode plates to the active patterns, and adjacent to each other in the first direction;
ferroelectric patterns between the plurality of electrode plates and the pair of common electrode patterns;
capacitor contacts extending through the first interlayer insulating layer on the active patterns, and between the pair of common electrode patterns and the edge portion of the active patterns; and
a second interlayer insulating layer covering the plurality of electrode plates on the first interlayer insulating layer,
wherein the bit line is in contact with an upper surface of the active patterns and an upper surface of the device isolation pattern.

20. The semiconductor memory device of claim 19, wherein the ferroelectric patterns comprise hafnium oxide and at least one of zirconium (Zr), silicon (Si), aluminum (Al), yttrium (Y), gadolinium (Gd), lanthanum (La), scandium (Sc), and strontium (Sr).
